(19) United States
(12) Patent Application Publication
(10) Pub. No.: US 2024/0052190 A1
(43) Pub. Date: Feb. 15, 2024

(54) INK COMPOSITION, LAYER USING SAME, AND ELECTROPHORESIS DEVICE AND DISPLAY DEVICE COMPRISING SAME

(71) Applicant: SAMSUNG SDI CO., LTD., Yongin-si, Gyeonggi-do (KR)

(72) Inventors: Jinsuop YOUN, Suwon-si (KR); Young Woo PARK, Suwon-si (KR); Young Min KIM, Suwon-si (KR); Misun KIM, Suwon-si (KR); Jiyoung JEONG, Suwon-si (KR); Janghyuk KIM, Suwon-si (KR); Eun Sun YU, Suwon-si (KR); Dong Wan RYU, Suwon-si (KR); Chuljin PARK, Suwon-si (KR); Bongyong KIM, Suwon-si (KR)

(21) Appl. No.: 18/282,199

(22) PCT Filed: Apr. 21, 2022
(86) PCT No.: PCT/KR2022/005686

§ 371 Date: Sep. 14, 2023

(30) Foreign Application Priority Data
May 11, 2021 (KR) 10-2021-0060892
Apr. 18, 2022 (KR) 10-2022-0047726

(51) Int. Cl. C09D 11/52; C09D 11/322; C09D 11/38; C09D 11/033; C09D 11/037; G02F 1/00; H01L 33/06; H01L 25/075

(52) U.S. Cl. CPC C09D 11/52; C09D 11/322; C09D 11/38; C09D 11/033; C09D 11/037; G02F 1/0018; H01L 33/06; H01L 25/0753

(57) ABSTRACT

Disclosed are an ink composition, a layer manufactured using the ink composition, and an electrophoresis device and a display device including the same. The ink composition includes (A) a semiconductor nanorod; and (B) a mixed solvent including a first solvent, a second solvent, and a third solvent, wherein the first solvent has a viscosity of less than or equal to 70 cps at 25° C. and includes a compound having a dielectric constant of greater than or equal to 5, the second solvent includes a compound having a viscosity of greater than or equal to 80 cps at 25° C. or being a solid or having a dielectric constant of greater than or equal to 5, and the third solvent includes a compound having a dielectric constant of less than 5.

### CROSS-REFERENCE TO RELATED APPLICATIONS

This application is a U.S. National Phase Patent Application of International Application Number PCT/KR2022/005686, filed on Apr. 21, 2022, which claims priority to Korean Patent Application Number 10-2021-0060892, filed on May 11, 2021, and Korean Patent Application Number 10-2022-0047726, filed on Apr. 18, 2022, the entire content of each of which is incorporated herein by reference.

### TECHNICAL FIELD

The present disclosure relates to an ink composition, a layer using the same, an electrophoresis device, and a display device including the same.

### BACKGROUND ART

LEDs have been actively developed since 1992 when Nakamura and others from Japanese Nichia Corp. succeeded in fusing a high-quality single crystal GaN nitride semiconductor by applying a low temperature GaN compound buffer layer. LED is a semiconductor device converting electric signals into light having wavelengths in a desired region by using characteristics of a compound semiconductor, which has a structure that an n-type semiconductor crystal in which a plurality of carriers is electrons and a p-type semiconductor crystal in which a plurality of carriers is holes are combined to each other.

This LED semiconductor has high light conversion efficiency and thus consumes very little energy and has a semipermanent life-span and also, is environmentally-friendly and thus called to be a revolution of light as a green material. Recently, high luminance red, orange, green, blue, and white LEDs have been developed with the development of compound semiconductor technology and are being applied in many fields such as traffic lights, mobile phones, car headlights, outdoor billboards, LCD BLU (back light unit), and indoor/outdoor lighting, which keeps being actively researched at home and abroad. Particularly, a GaN-based compound semiconductor having a wide bandgap is a material used to manufacture a LED semiconductor emitting light in green, blue, and ultraviolet (UV) regions, and since a blue LED device is used to manufacture a white LED device, lots of research is being made on this.

Among these series of studies, studies using ultra-small LED devices having a nano or micro unit size are being actively conducted, and in addition studies for utilizing these ultra-small LED devices in lighting and displays are being continuously made. In these studies, electrodes capable of applying power to the ultra-small LED devices, disposition of the electrodes for reducing a space occupied by the electrodes, a method of mounting the ultra-small LED devices on the disposed electrodes, and the like are continuously attracting attentions.

Among these, the method of mounting the ultra-small LED devices on the disposed electrodes still have difficulties of disposing and mounting the ultra-small LED devices on the electrodes as intended due to size limitations of the ultra-small LED devices. The reason is that the ultra-small LED devices are nano-scale or micro-scale and thus may not be one by one disposed and mounted by hand on a target electrode region.

Recently, as the demand for the nano-scale ultra-small LED devices is increasing, an attempt to manufacture a nano-scale GaN-based or InGaN-based compound semiconductor into a rod has been made, but there is a problem that dispersion stability of a nanorod itself in a solution (or a polymerizable compound) is greatly deteriorated. Until now, there has been no introduction of a technology of improving the dispersion stability of the semiconductor nanorod in a solution (or a polymerizable compound). Accordingly, research on a curable composition containing semiconductor nanorods capable of improving dispersion stability in a solvent (or polymerizable compound) of semiconductor nanorods and implementing a high dielectrophoresis rate is continued.

### DISCLOSURE

### Technical Problem

An embodiment provides an ink composition having excellent electrophoretic properties, ink jetting properties, and storage stability of semiconductor nanorods.

Another embodiment provides a layer manufactured using the ink composition.

Another embodiment provides an electrophoresis device and a display device including the layer.

### Technical Solution

An embodiment provides an ink composition including (A) semiconductor nanorods; and (B) a mixed solvent including a first solvent, a second solvent, and a third solvent, wherein the first solvent has a viscosity of less than or equal to 70 cps at 25° C. and includes a compound having a dielectric constant of greater than or equal to 5, the second solvent includes a compound having a viscosity of greater than or equal to 80 cps at 25° C. or being a solid or having a dielectric constant of greater than or equal to 5, and the third solvent includes a compound having a dielectric constant of less than 5.

The first solvent may have a viscosity of greater than or equal to 3 cps at 50° C.

The first solvent may include a compound represented by Chemical Formula 1-1 or Chemical Formula 1-2.

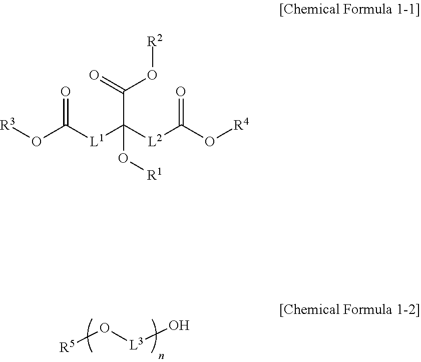

In Chemical Formula 1-1 and Chemical Formula 1-2,
R¹ is a hydrogen atom or *—C(═O)R′, wherein R′ is a hydrogen atom or a substituted or unsubstituted C1 to C10 alkyl group,
R² to R⁴ are each independently a substituted or unsubstituted C2 to C20 alkyl group,
R⁵ is a substituted or unsubstituted C1 to C20 alkyl group or a substituted or unsubstituted C6 to C20 aryl group substituted with a C2 to C10 alkoxy group,
L¹ to L³ are each independently a substituted or unsubstituted C1 to C20 alkylene group, and
n is an integer of 1 to 20.

The compound represented by Chemical Formula 1-1 may include a compound represented by Chemical Formula 1-1-1 or 1-1-2.

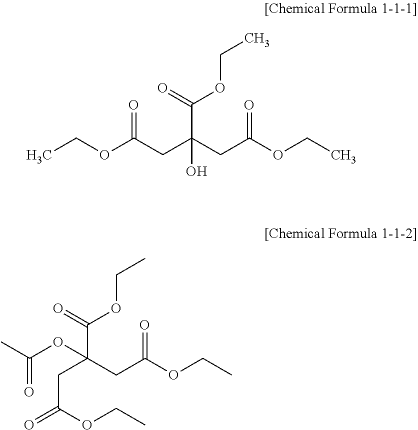

The compound represented by Chemical Formula 1-2 may include a compound represented by Chemical Formulae 1-2-1 to 1-2-4.

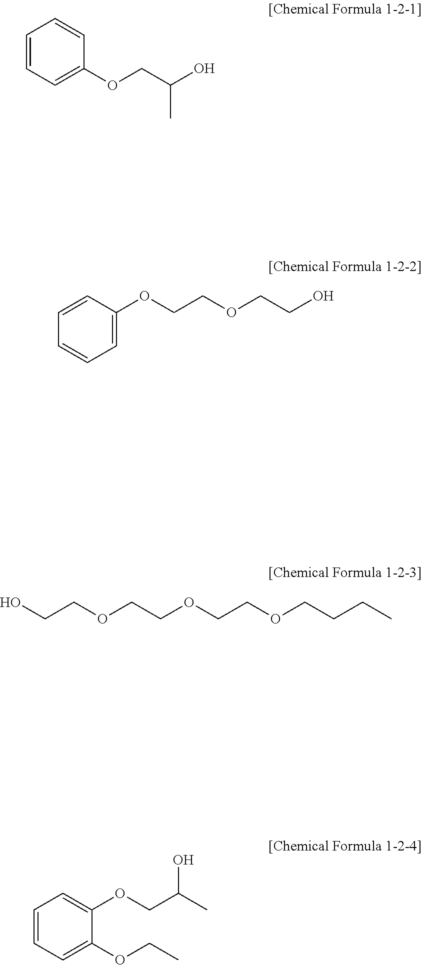

The second solvent may have a viscosity of greater than or equal to 10 cps at 50° C. or may be a solid.

The second solvent may include a compound represented by one of Chemical Formula 2-1 to Chemical Formula 2-6.

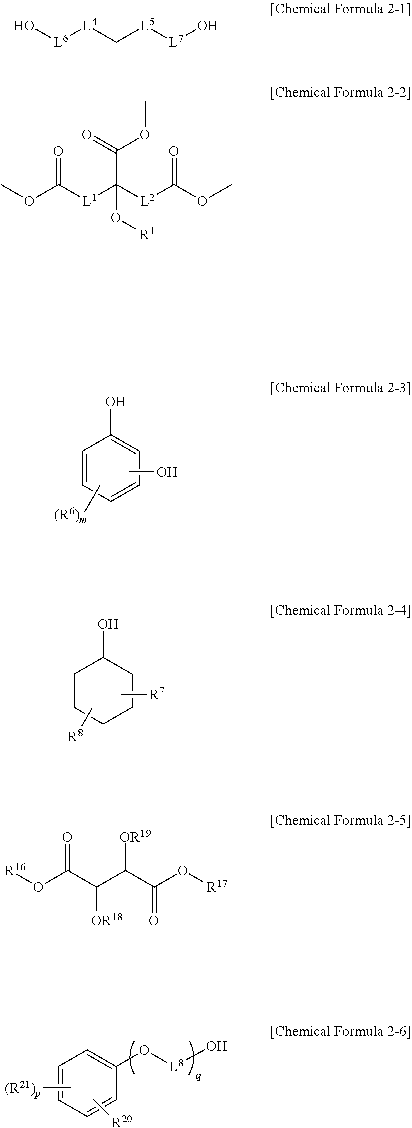

In Chemical Formula 2-1 to Chemical Formula 2-6,
L¹, L², and L⁴ to L⁸ are each independently a substituted or unsubstituted C1 to C20 alkylene group,
R¹ is a hydrogen atom or *—C(═O)R′, wherein R′ is a hydrogen atom or a substituted or unsubstituted C1 to C10 alkyl group,
R⁶ is a hydroxy group or a substituted or unsubstituted C1 to C20 alkyl group,
R⁷ and R⁸ are each independently a substituted or unsubstituted C1 to C20 alkyl group,
R¹⁶ and R¹⁷ are each independently a hydrogen atom, a substituted or unsubstituted C1 to C20 alkyl group, a substituted or unsubstituted C3 to C20 cycloalkyl group, or a substituted or unsubstituted C6 to C20 aryl group,
R¹⁸ and R¹⁹ are each independently a hydrogen atom or *—(C═O)R¹⁵, wherein R¹⁵ is a substituted or unsubstituted C1 to C20 alkyl group, a substituted or unsubstituted C3 to C20 cycloalkyl group, or a substituted or unsubstituted C6 to C20 aryl group,
R²⁰ is a methoxy group,
R²¹ is a substituted or unsubstituted C1 to C20 alkyl group or a substituted or unsubstituted C1 to C20 alkoxy group,
m is an integer of 1 to 4, and
p is an integer of 1 to 20.

The compound represented by Chemical Formula 2-1 may include a compound represented by Chemical Formula 2-1-1.

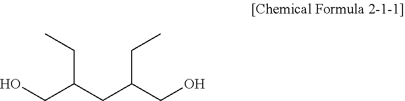

The compound represented by Chemical Formula 2-2 may include a compound represented by Chemical Formula 2-2-1.

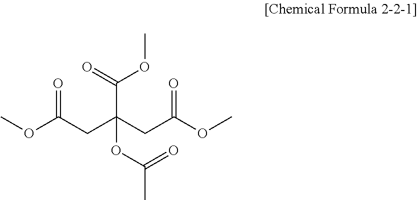

The compound represented by Chemical Formula 2-3 may include a compound represented by one of Chemical Formula 2-3-1 to Chemical Formula 2-3-3.

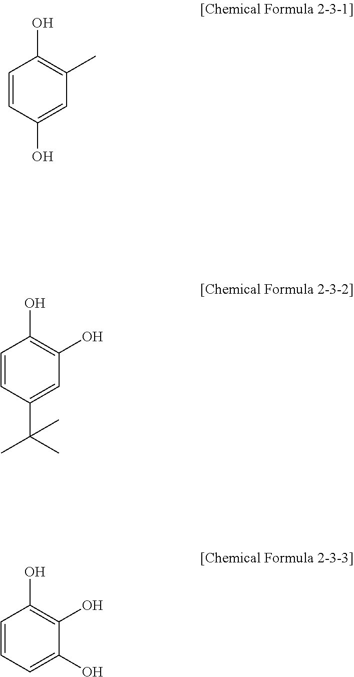

The compound represented by Chemical Formula 2-4 may include a compound represented by Chemical Formula 2-4-1.

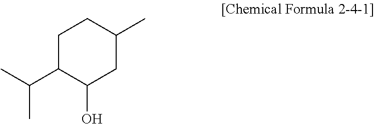

The compound represented by Chemical Formula 2-5 may include a compound represented by one of Chemical Formula 2-5-1 and Chemical Formula 2-5-2.

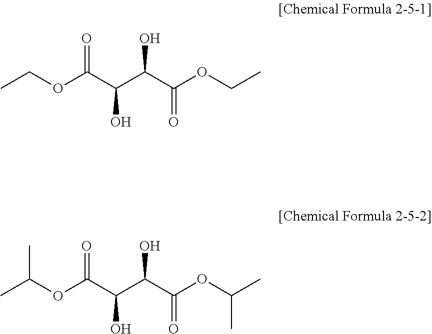

The compound represented by Chemical Formula 2-6 may include a compound represented by one of Chemical Formula 2-6-1 to Chemical Formula 2-6-3.

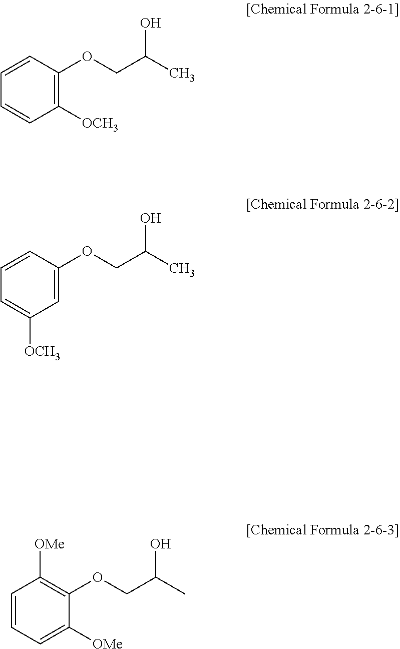

The third solvent may have a viscosity of greater than or equal to 70 cps at 25° C. or may be a solid, and may have a viscosity of greater than or equal to 3 cps at 50° C.

The third solvent may include a compound represented by one of Chemical Formula 3-1 or Chemical Formula 3-2.

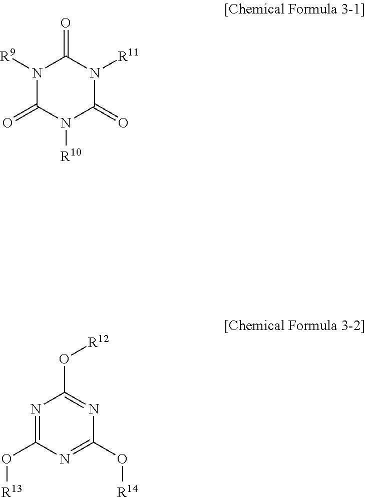

In Chemical Formula 3-1 and Chemical Formula 3-2,
R⁹ to R¹⁴ are each independently a C1 to C20 alkyl group unsubstituted or substituted with a vinyl group.

The compound represented by Chemical Formula 3-1 may include a compound represented by Chemical Formula 3-1-1.

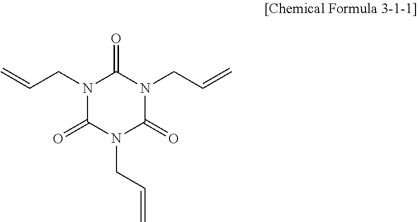 [SMILES: C=CCn1c(=O)n(CC=C)c(=O)n(CC=C)c1=O]

The compound represented by Chemical Formula 3-2 may include a compound represented by Chemical Formula 3-2-1.

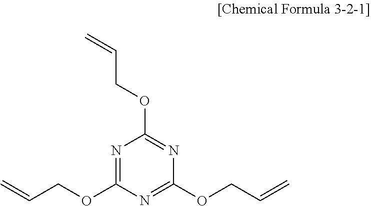 [SMILES: C=CCOc1nc(OCC=C)nc(OCC=C)n1]

The first solvent may be included in an amount of 10 parts by weight to 50 parts by weight based on 100 parts by weight of the mixed solvent.

The second solvent may be included in an amount of 10 parts by weight to 40 parts by weight based on 100 parts by weight of the mixed solvent.

The third solvent may be included in an amount of 20 to 50 parts by weight based on 100 parts by weight of the mixed solvent.

The semiconductor nanorods may have a diameter of 300 nm to 900 nm.

The semiconductor nanorods may have a length of 3.5 μm to 5 μm.

The semiconductor nanorods may include a GaN-based compound, an InGaN-based compound, or a combination thereof.

The semiconductor nanorods may have a surface coated with a metal oxide.

The metal oxide may include alumina, silica, or a combination thereof.

The semiconductor nanorods may be included in an amount of 0.01 wt % to 10 wt % based on the total amount of the ink composition.

The ink composition may further include malonic acid; 3-amino-1,2-propanediol; a silane-based coupling agent; a leveling agent; a fluorine-based surfactant; or a combination thereof.

The ink composition may be an ink composition for an electrophoresis device.

Another embodiment provides a layer manufactured using the ink composition.

Another embodiment provides an electrophoresis device including the layer.

Another embodiment provides a display device including the layer.

Other embodiments of the present invention are included in the following detailed description.

### Advantageous Effects

The ink composition including the semiconductor nanorods may provide a curable composition having excellent electrophoretic properties, ink jetting properties, and storage stability.

### DESCRIPTION OF DRAWINGS

FIG. 1 is an example of a cross-sectional view of a semiconductor nanorod used in a curable composition according to an embodiment.

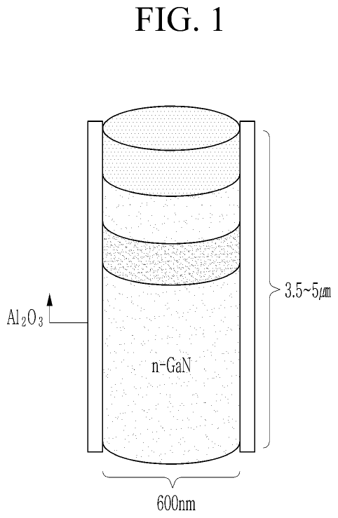

### BEST MODE

Hereinafter, embodiments of the present invention are described in detail. However, these embodiments are exemplary, the present invention is not limited thereto and the present invention is defined by the scope of claims.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen by a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid group or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, the term “hetero” refers to one including at least one heteroatom selected from N, O, S and P in a chemical formula.

As used herein, when specific definition is not otherwise provided, “(meth)acrylate” refers to both “acrylate” and “methacrylate”, and “(meth)acrylic” refers to “acrylic” and “methacrylic.”

As used herein, when specific definition is not otherwise provided, “combination” refers to mixing or copolymerization.

As used herein, unless a specific definition is otherwise provided, a hydrogen atom is boned at the position when a chemical bond is not drawn where supposed to be given.

As used herein, “semiconductor nanorod” refers to a rod-shaped semiconductor having a nano-sized diameter.

As used herein, when specific definition is not otherwise provided, “*” indicates a point where the same or different atom or chemical formula is linked.

An ink composition according to an embodiment includes (A) semiconductor nanorods; and (B) a mixed solvent including a first solvent, a second solvent, and a third solvent, wherein the first solvent has a viscosity of less than or equal to 70 cps at 25° C. and includes a compound having a dielectric constant of greater than or equal to 5, the second solvent includes a compound having a viscosity of greater than or equal to 80 cps at 25° C. or being a solid or having a dielectric constant of greater than or equal to 5, and the third solvent includes a compound having a dielectric constant of less than 5.

Recently, studies on various concepts having effects of improving energy efficiency and preventing efficiency drop of conventional LEDs such as micro LED, mini LED, and the like have been actively conducted. Among them, an alignment (electrophoresis) of InGaN-based nanorod LEDs using an electric field draws attentions as a method of dramatically reducing complex and expensive process costs of the micro LED, the mini LED, and the like.

However, organic solvents (PGMEA, GBL, PGME, ethyl acetate, IPA, and the like) conventionally used in a display and an electronic material have low viscosity and thus inorganic nanorod particles having high density may be sedimented too fast and thus agglomerated, and in addition, may be fast volatilized and thus may deteriorate alignment characteristics during the solvent drying after the dielectrophoresis. Accordingly, in order to develop an ink composition including the inorganic material nanorods (semiconductor nanorods), a solvent with excellent dielectrophoretic properties due to high viscosity and a high boiling point is required to improve sedimentation stability of the nanorods, and the inventors of the present invention, after numerous trials and errors, have significantly improved electrophoretic properties and particularly, a normal alignment degree of the semiconductor nanorods in the ink composition as well as maintained ink jetting properties of the ink composition and also, realized excellent storage stability by controlling the solvent used with the semiconductor nanorods to a three-component system.

Hereinafter, each component is described in detail.

### (A) Semiconductor Nanorods

The semiconductor nanorods may include a GaN-based compound, an InGaN-based compound, or a combination thereof, and the surface thereof may be coated with a metal oxide.

In order to secure dispersion stability of a semiconductor nanorod ink solution (semiconductor nanorods+solvent), it usually takes 3 hours, which is insufficient time to perform a large area inkjet process. Accordingly, the inventors of the present invention have developed an insulating film (Al₂O₃ or SiOₓ) by coating a metal oxide such as alumina, silica, or a combination thereof on the surface of a semiconductor nanorod after numerous trial and error studies to maximize compatibility with a solvent described below.

For example, the insulating film coated with the metal oxide may have a thickness of 40 nm to 60 nm.

The semiconductor nanorods include an n-type confinement layer and a p-type confinement layer, and a multi quantum well (MQW) active region active region may be disposed between the n-type confinement layer and the p-type confinement layer.

For example, the semiconductor nanorods may have a diameter of 300 nm to 900 nm, for example, 600 nm to 700 nm.

For example, the semiconductor nanorods may have a length of 3.5 μm to 5 μm.

For example, when the semiconductor nanorods may include an alumina insulating layer, it may have a density of 5 g/cm³ to 6 g/cm³.

For example, the semiconductor nanorods may have a mass of 1×10⁻¹³ g to 1×10⁻¹¹ g.

When the semiconductor nanorods have the above diameter, length, density and type, the surface coating of the metal oxide may be easily performed, so that dispersion stability of the semiconductor nanorods may be maximized.

The semiconductor nanorods may be included in an amount of 0.01 wt % to 10 wt %, for example 0.01 wt % to 5 wt % based on the total amount of the ink composition. Alternatively, the semiconductor nanorods may be included in an amount of 0.01 parts by weight to 0.5 parts by weight, for example, 0.01 parts by weight to 0.1 parts by weight, based on 100 parts by weight of the solvent in the ink composition. When the semiconductor nanorods are included within the above range, dispersibility in the ink is good, and the prepared pattern may have excellent luminance.

### (B) Solvent

The ink composition according to an embodiment includes a mixed solvent including three different solvents (a first solvent, a second solvent, and a third solvent) each satisfying different conditions.

In recent years, as the needs for nano-scale micro LED devices are increasing, there has been an attempt to manufacture a nano-scale GaN-based or InGaN-based compound semiconductor as a rod, but a nanorod itself has a problem that dispersion stability in a solution (or a polymerizable compound) is greatly deteriorated. Until now, there has been no introduction of a technology of improving the dispersion stability of the semiconductor nanorods in a solvent.

Organic solvents such as propylene glycol monomethyl ether acetate (PEGMEA), Y-butyrolactone (GBL), polyethylene glycol methyl ether (PGME), ethylacetate, isopropylalcohol (IPA), and the like, which have been used in conventional displays and electron materials have so low viscosity that inorganic material nanorod particles with high density are too fast sedimented, resulting in unsatisfactory dielectrophoretic properties. Therefore, as described above, for the development of an ink composition for an electrophoresis device including inorganic nanorods (semiconductor nanorods), a solvent capable of imparting sedimentation stability of the nanorods may be used.

Since the ink composition according to an embodiment has a large viscosity difference at room temperature (25° C.) and 50° C., the nanorods are slowly sedimented at the room temperature (25° C.), but since the ink composition has viscosity of less than or equal to 15 cps at 50° C., an ink-jetting process may be applied, and simultaneously, a dielectric constant may be controlled according to a composition ratio (a mixing weight ratio of three types of solvents). In other words, the ink composition according to an embodiment may secure storage stability (high viscosity at room temperature) and exhibit inkjet processibility (less than or equal to 15 cps of viscosity at 50° C.) and high dielectrophoretic (low electrical conductivity and controllable dielectric constant) characteristics. That is, when a three-component solvent system rather than a conventional one or two component solvent system is applied, desired viscosity and dielectric constant are secured by easily controlling the solvent component ratio (mixing weight ratio) of the three components, which makes the ink composition according to an embodiment completely different from the conventional ink composition in terms of the inventive concept.

For example, the first solvent may have a viscosity of greater than or equal 3 cps at 50° C.

The first solvent may include a compound represented by Chemical Formula 1-1 or Chemical Formula 1-2.

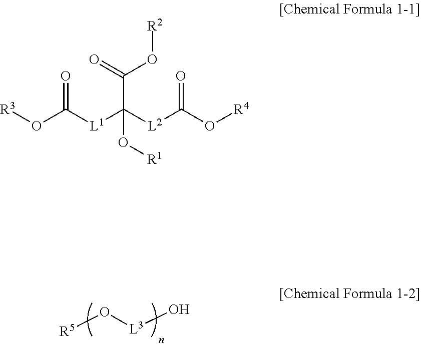

In Chemical Formula 1-1 and Chemical Formula 1-2,
R¹ is a hydrogen atom or *—C(═O)R′, wherein R′ is a hydrogen atom or a substituted or unsubstituted C1 to C10 alkyl group,
R² to R⁴ are each independently a substituted or unsubstituted C2 to C20 alkyl group,
R⁵ is a substituted or unsubstituted C1 to C20 alkyl group or a substituted or unsubstituted C6 to C20 aryl group substituted with a C2 to C10 alkoxy group,
L¹ to L³ are each independently a substituted or unsubstituted C1 to C20 alkylene group, and
n is an integer of 1 to 20.

For example, the compound represented by Chemical Formula 1-1 may include a compound represented by Chemical Formula 1-1-1 or Chemical Formula 1-1-2.

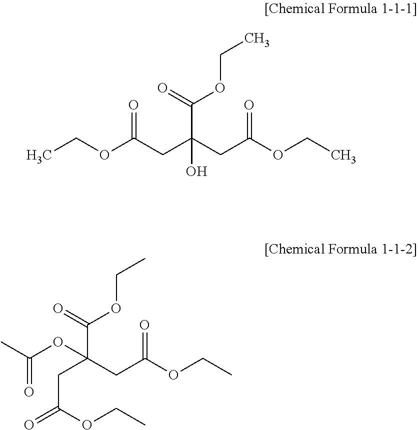

For example, the compound represented by Chemical Formula 1-2 may include a compound represented by Chemical Formula 1-2-1 to Chemical Formula 1-2-4.

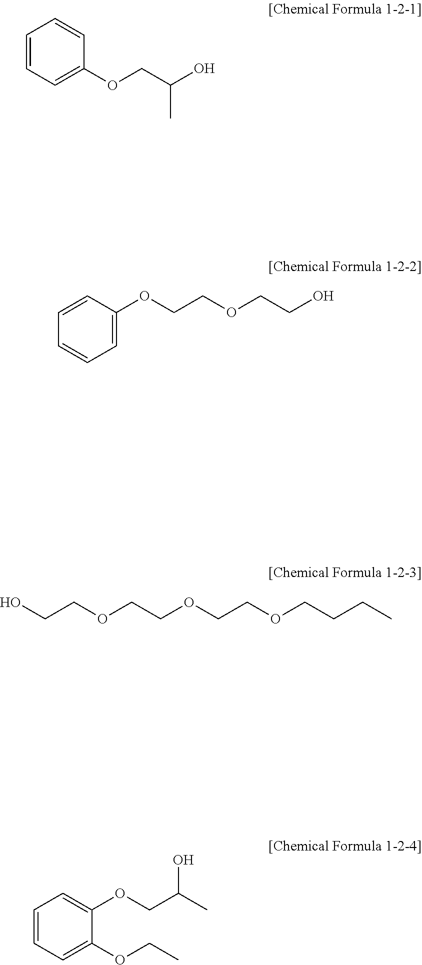

For example, the second solvent may have a viscosity of greater than or equal to 10 cps at 50° C. or may be a solid.

For example, the second solvent may include a compound represented by one of Chemical Formula 2-1 to Chemical Formula 2-6.

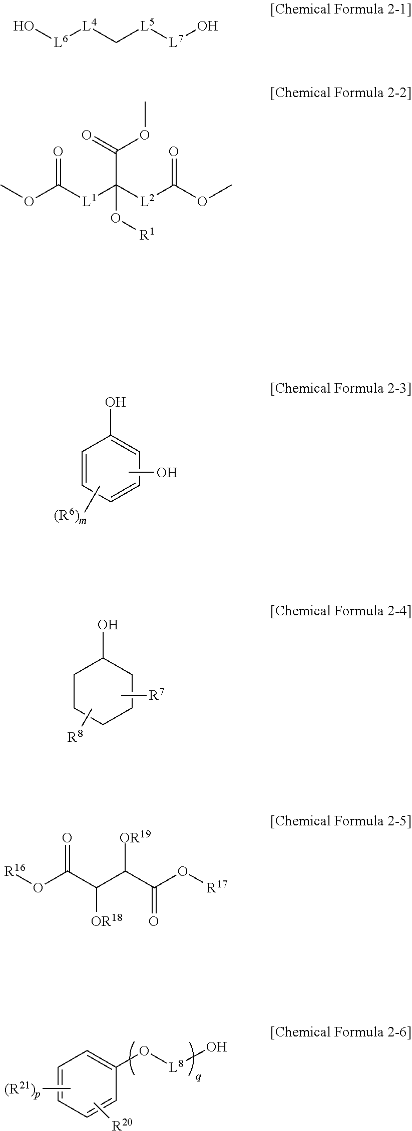

In Chemical Formula 2-1 to Chemical Formula 2-6,
L¹, L², and L⁴ to L⁸ are each independently a substituted or unsubstituted C1 to C20 alkylene group,
R¹ is a hydrogen atom or *—C(═O)R′, wherein R′ is a hydrogen atom or a substituted or unsubstituted C1 to C10 alkyl group,
R⁶ is a hydroxy group or a substituted or unsubstituted C1 to C20 alkyl group,
R⁷ and R⁸ are each independently a substituted or unsubstituted C1 to C20 alkyl group,
R¹⁶ and R¹⁷ are each independently a hydrogen atom, a substituted or unsubstituted C1 to C20 alkyl group, a substituted or unsubstituted C3 to C20 cycloalkyl group, or a substituted or unsubstituted C6 to C20 aryl group,
R¹⁸ and R¹⁹ are each independently a hydrogen atom or *—(C═O)R¹⁵, wherein R¹⁵ is a substituted or unsubstituted C1 to C20 alkyl group, a substituted or unsubstituted C3 to C20 cycloalkyl group, or a substituted or unsubstituted C6 to C20 aryl group,
R²⁰ is a methoxy group,
R²¹ is a substituted or unsubstituted C1 to C20 alkyl group or a substituted or unsubstituted C1 to C20 alkoxy group,
m is an integer of 1 to 4, and
p is an integer of 1 to 20.

For example, the compound represented by Chemical Formula 2-1 may include a compound represented by Chemical Formula 2-1-1.

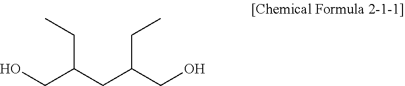

For example, the compound represented by Chemical Formula 2-2 may include a compound represented by Chemical Formula 2-2-1.

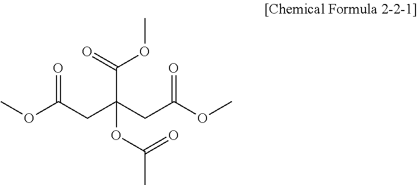

For example, the compound represented by Chemical Formula 2-3 may include a compound represented by one of Chemical Formula 2-3-1 to Chemical Formula 2-3-3.

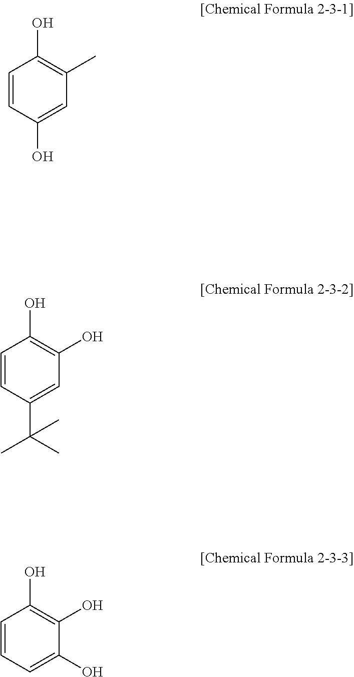

For example, the compound represented by Chemical Formula 2-4 may include a compound represented by Chemical Formula 2-4-1.

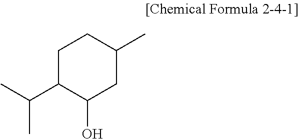

The compound represented by Chemical Formula 2-5 may include a compound represented by one of Chemical Formula 2-5-1 and Chemical Formula 2-5-2.

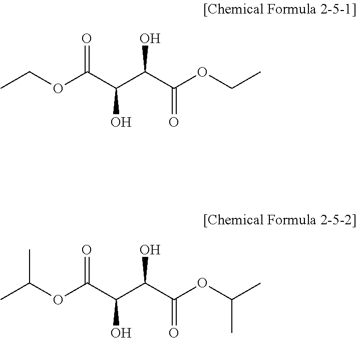

The compound represented by Chemical Formula 2-6 may include a compound represented by one of Chemical Formula 2-6-1 to Chemical Formula 2-6-3.

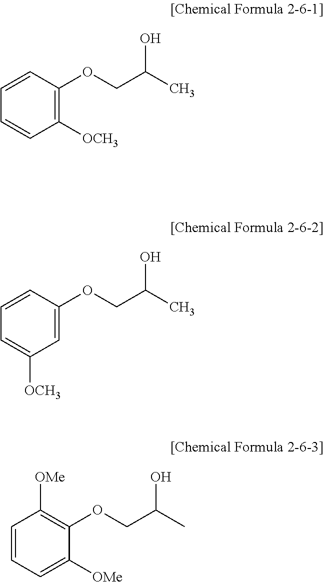

For example, the third solvent may have a viscosity of greater than or equal to 70 cps at 25° C. or may be a solid, and may have a viscosity of greater than or equal to 3 cps at 50° C.

For example, the third solvent may include a compound represented by one of Chemical Formula 3-1 or Chemical Formula 3-2.

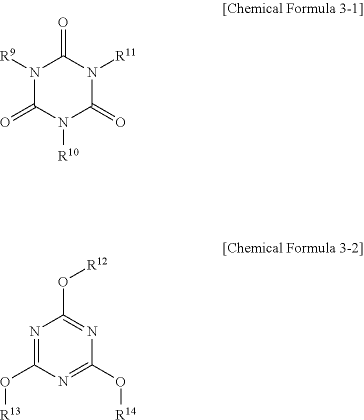

In Chemical Formula 3-1 and Chemical Formula 3-2,
R⁹ to R¹⁴ are each independently a C1 to C20 alkyl group unsubstituted or substituted with a vinyl group.

For example, the compound represented by Chemical Formula 3-1 may include a compound represented by Chemical Formula 3-1-1.

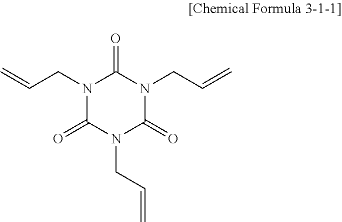 [SMILES: C=CCn1c(=O)n(CC=C)c(=O)n(CC=C)c1=O]

For example, the compound represented by Chemical Formula 3-2 may include a compound represented by Chemical Formula 3-2-1.

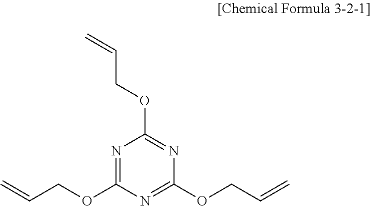 [SMILES: C=CCOc1nc(OCC=C)nc(OCC=C)n1]

The viscosity and dielectric constant of each of the compounds represented by Chemical Formula 1-1-1 to Chemical Formula 3-2-1 are shown in Table 1.

TABLE 1

| | Chemical | Viscosity | Viscosity | Dielectric |
|---|---|---|---|---|
| | Formula | (25° C.) | (50° C.) | constant |
| First solvent | 1-1-1 | 30 | 9.7 | 11 |
| | 1-1-2 | 43.1 | 12.3 | 8.4 |
| | 1-2-1 | 26.1 | 4.3 | 8.5 |
| | 1-2-2 | 33 | 9.6 | 11.2 |
| | 1-2-3 | 8.5 | 4 | 9.8 |
| | 1-2-4 | 53 | 11 | 6.5 |
| Second solvent | 2-1-1 | 1023 | 133 | 19.4 |
| | 2-2-1 | 354 | 43.4 | 9.6 |
| | 2-3-1 | solid | solid | — |
| | 2-3-2 | solid | solid | — |
| | 2-3-3 | solid | solid | — |
| | 2-4-1 | solid | 10.2 | 5.0* |
| | 2-5-1 | 127 | 21 | 13.5 |
| | 2-5-2 | 288 | 35 | 9.2 |
| | 2-6-1 | 124 | 18 | 7.5 |
| | 2-6-2 | 94 | 17 | 7.7 |
| | 2-6-3 | 89 | 17 | 7.9 |
| Third solvent | 3-1-1 | 144 | 23.4 | 2.7 |
| | 3-2-1 | solid | 8.5 | 2.9* |

(*50° C. dielectric constant)

The first solvent may be included in an amount of 10 parts by weight to 50 parts by weight based on 100 parts by weight of the mixed solvent.

The second solvent may be included in an amount of 10 parts by weight to 40 parts by weight based on 100 parts by weight of the mixed solvent.

The third solvent may be included in an amount of 20 parts by weight to 50 parts by weight based on 100 parts by weight of the mixed solvent.

The solvent may be included in an amount of 5 wt % to 99 wt %, for example 20 wt % to 99.7 wt %, based on the total amount of the ink composition.

### Polymerizable Monomer

In some cases, the ink composition according to the embodiment may further include a polymerizable compound. The polymerizable compound may be used by mixing monomers or oligomers generally used in conventional curable compositions.

For example, the polymerizable compound may be a polymerizable monomer having a carbon-carbon double bond at the terminal end.

For example, the polymerizable compound may be a polymerizable monomer having at least one functional group represented by Chemical Formula A-1 or a functional group represented by Chemical Formula A-2 at the terminal end.

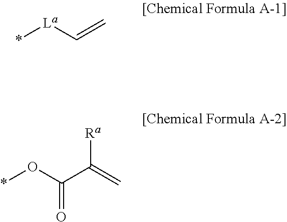

In Chemical Formula A-1 and Chemical Formula A-2,
L^{a} is a substituted or unsubstituted C1 to C20 alkylene group, and
R^{a} is a hydrogen atom or a substituted or unsubstituted C1 to C20 alkyl group.

The polymerizable compound includes at least one carbon-carbon double bond at the terminal end and specifically, a functional group represented by Chemical Formula A-1 or A-2 and thus may form a crosslinked structure with a surface-modified compound, and this crosslinked structure may further double a type of steric hindrance effect and much improve dispersion stability of the semiconductor nanorods.

For example, the polymerizable compound including at least one functional group represented by Chemical Formula A-1 at the terminal end may be divinyl benzene, triallyl cyanurate, triallyl isocyanurate, triallyl trimellitate, triallyl phosphate, triallyl phosphite, triallyl triazine, diallyl phthalate, or a combination thereof, but is not necessarily limited thereto.

For example, the polymerizable compound including at least one functional group represented by Chemical Formula A-2 at the terminal end may be ethylene glycol diacrylate, triethylene glycol diacrylate, 1,4-butanediol diacrylate, 1,6-hexane diol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, polyfunctional epoxy (meth) acrylate, polyfunctional urethane (meth)acrylate, KAYARAD DPCA-20, KAYARAD DPCA-30, KAYARAD DPCA-60, KAYARAD DPCA-120, KAYARAD DPEA-12 of Nippon Chemical, or a combination thereof, but is not necessarily limited thereto.

The polymerizable compound may be used by treating it with an acid anhydride in order to impart more excellent developability.

### Polymerization Initiator

The curable composition according to the embodiment may further include a polymerization initiator, for example, a photopolymerization initiator, a thermal polymerization initiator, or a combination thereof, if necessary.

The photopolymerization initiator may be an initiator generally used in curable ink compositions, for example, an acetophenone-based compound, a benzophenone-based compound, a thioxanthone-based compound, a benzoin-based compound, a triazine-based compound, an oxime-based compound, and an aminoketone-based compound, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may include benzophenone, benzoyl benzoate, benzoyl methyl benzoate, 4-phenyl benzophenone, hydroxybenzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenonem, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include an O-acyloxime compound, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may include 1,2-octanedione, 2-dimethylamino-2-(4-methylbenzyl)-1-(4-morpholin-4-yl-phenyl)-butane-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octan-1-oneoxime-O-acetate, 1-(4-phenylsulfanylphenyl)-butan-1-oneoxime-O-acetate, and the like.

Examples of the am inoketone-based compound may include 2-benzyl-2-dimethylamino-1-(4-morpholinophenyI)-butanone-1.

The photopolymerization initiator may further include a carbazole-based compound, a diketone-based compound, a sulfonium borate-based compound, a diazo-based compound, an imidazole-based compound, a biimidazole-based compound, and the like, besides the compounds.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may be peroxide, specifically, benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and the like and also, 2,2′-azobis-2-methylpropinonitrile and the like, but are not necessarily limited thereto and may include anything widely known in the related field.

The polymerization initiator may be included in an amount of 1 wt % to 5 wt %, for example 2 wt % to 4 wt % based on the total solid amount of the ink composition. When the polymerization initiator is included within the ranges, the ink composition may be sufficiently cured during the exposure or thermal curing and thus obtain excellent reliability.

### Other Additives

The curable composition according to an embodiment may further include a polymerization inhibitor including a hydroquinone-based compound, a catechol-based compound, or a combination thereof, as needed. As the ink composition according to an embodiment further includes the hydroquinone-based compound, catechol-based compound, or combination thereof, after printing (coating) an ink composition, crosslinking at room temperature may be prevented during exposure.

For example, the hydroquinone-based compound, catechol-based compound, or combination thereof may include hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′) aluminium, or a combination thereof, but is not necessarily limited thereto.

The hydroquinone-based compound, catechol-based compound, or combination thereof may be used in a dispersion type and the dispersion-type polymerization inhibitor may be included in an amount of 0.001 wt % to 1 wt %, for example 0.01 wt % to 0.1 wt %, based on the total amount of the ink composition. When the stabilizer is included within the above range, the problem with aging at room temperature may be solved and sensitivity reduction and surface peeling may be prevented.

The ink composition according to an embodiment may further include malonic acid; 3-amino-1,2-propanediol; a silane-based coupling agent; a leveling agent; a fluorine-based surfactant; or a combination thereof in addition to the polymerization inhibitor, as needed.

For example, the ink composition may further include a silane-based coupling agent having a reactive substituent such as a carboxyl group, a methacryloyl group, an isocyanate group, an epoxy group, and the like to improve its adherence to a substrate.

Examples of the silane-based coupling agent may include trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexypethyltrimethoxysilane, and the like. These may be used alone or in a mixture of two or more.

The silane-based coupling agent may be included in an amount of 0.01 parts by weight to 10 parts by weight based on 100 parts by weight of the ink composition. When the silane-coupling agent is included within the range, close contacting property, storing property, and the like may be improved.

In addition, the ink composition may further include a surfactant, for example a fluorine-based surfactant to improve coating and prevent a defect if necessary.

Examples of the fluorine-based surfactant may be BM-1000® and BM-1100® of BM Chemie Inc.; MEGAFACE F 142D®, MEGAFACE F 172®, MEGAFACE F 173®, and MEGAFACE F 183® of Dainippon Ink Kagaku Kogyo Co., Ltd.; FULORAD FC-135®, FULORAD FC-170C®, FULORAD FC-430®, and FULORAD FC-431® of Sumitomo 3M Co., Ltd.; SURFLON S-112®, SURFLON S-113®, SURFLON S-131®, SURFLON S-141®, and SURFLON S-145® of ASAHI Glass Co., Ltd.; and SH-28PA®, SH-190®, SH-193®, SZ-6032®, and SF-8428®, and the like of Toray Silicone Co., Ltd.; F-482, F-484, F-478, F-554, and the like of DIC Co., Ltd.

The fluorine-based surfactant may be included in an amount of 0.001 parts by weight to 5 parts by weight based on 100 parts by weight of the ink composition. When the fluorine-based surfactant is included within the above range, excellent wetting on a glass substrate as well as coating uniformity may be secured, and a stain may not be produced.

In addition, a certain amount of other additives such as antioxidants and stabilizers may be further added to the ink composition within a range that does not impair physical properties.

Another embodiment provides a layer using the ink composition.

Another embodiment provides an electrophoresis device and/or a display device including the layer.

### MODE FOR INVENTION

Hereinafter, the present invention is illustrated in more detail with reference to examples. These examples, however, are not in any sense to be interpreted as limiting the scope of the invention.

### Preparation of Curable Composition

### Examples 1 to 6 and Comparative Examples 1 to 3

A nanorod-patterned GaN wafer (4 inches) was reacted in 40 ml of stearic acid (1.5 mM) at room temperature for 24 hours. After the reaction, the nanorod-patterned GaN was dipped in 50 ml of acetone for 5 minutes to remove an excessive amount of the stearic acid, and additionally, 40 ml of acetone was used to rinse the surface of the wafer. The washed wafer was placed with 35 ml of γ-butyrolactone (GBL) in a 27 kW bath-type sonicator and then, sonicated for 5 minutes to separate the rods from the wafer surface. The separated rods were placed in a FALCON tube for a centrifuge, and 10 ml of GBL was added thereto to additionally wash the rods on the surface of the bath. Then, a supernatant was discarded therefrom through centrifugation at 4000 rpm for 10 minutes, and precipitates therein were redispersed in 40 ml of acetone and filtered with a 10 μm mesh filter. After additional centrifugation (4000 rpm, 10 minutes), the precipitate was dried in a drying oven (100° C. for 1 hour), weighed, and dispersed to be 0.2 w/w % to prepare each ink composition having compositions shown in Table 2.

(The composition of the mixed solvent and the dielectric constant and viscosity of the solvent are shown in Table 3.)

TABLE 2
(unit: wt %)

| | Amount |
|---|---|
| (A) GaN nanorods | 0.2 |
| (B) Mixed solvent | 99.8 |

TABLE 3

| | | | | | | | | Compar- | Compar- | Compar- |
|---|---|---|---|---|---|---|---|---|---|---|
| | | | | | | | | ative | ative | ative |
| | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 1 | ple 2 | ple 3 |
| Mixed | Chemical | Chemical | Chemical | — | — | — | Chemical | — | — | — |
| solvent | Formula | Formula | Formula | | | | Formula | | | |
| (wt %) | 1-2-1 | 1-2-1 | 1-2-1 | | | | 1-2-1 | | | |
| | (25) | (64) | (49.5) | | | | (50) | | | |
| | — | — | — | Chemical | Chemical | Chemical | — | — | Chemical | — |
| | | | | Formula | Formula | Formula | | | Formula | |
| | | | | 1-1-1 | 1-1-1 | 1-1-1 | | | 1-1-1 | |
| | | | | (45) | (34) | (36) | | | (60) | |
| | — | — | — | — | — | — | — | Chemical | — | — |
| | | | | | | | | Formula | | |
| | | | | | | | | 1-2-2 | | |
| | | | | | | | | (100) | | |
| | — | — | — | — | — | — | — | — | — | — |
| | Chemical | — | — | Chemical | — | — | Chemical | — | Chemical | Chemical |
| | Formula | | | Formula | | | Formula | | Formula | Formula |
| | 2-2-1 | | | 2-2-1 | | | 2-2-1 | | 2-2-1 | 2-2-1 |
| | (55) | | | (13) | | | (20) | | (40) | (20) |
| | — | Chemical | — | — | — | — | — | — | — | — |
| | | Formula | | | | | | | | |
| | | 2-3-1 | | | | | | | | |
| | | (11) | | | | | | | | |
| | — | — | Chemical | — | — | — | — | — | — | — |
| | | | Formula | | | | | | | |
| | | | 2-3-2 | | | | | | | |
| | | | (17.5) | | | | | | | |
| | — | — | — | — | Chemical | — | — | — | — | — |
| | | | | | Formula | | | | | |
| | | | | | 2-1-1 | | | | | |
| | | | | | (23) | | | | | |
| | — | — | — | — | — | Chemical | — | — | — | — |
| | | | | | | Formula | | | | |
| | | | | | | 2-5-1 | | | | |
| | | | | | | (27) | | | | |
| | Chemical | Chemical | Chemical | Chemical | Chemical | Chemical | Chemical | — | — | Chemical |
| | Formula | Formula | Formula | Formula | Formula | Formula | Formula | | | Formula |
| | 3-1-1 | 3-1-1 | 3-1-1 | 3-1-1 | 3-1-1 | 3-1-1 | 3-1-1 | | | 3-1-1 |
| | (20) | (25) | (33) | (42) | (43) | (37) | (30) | | | (80) |

*The dielectric constant of the mixed solvent was measured by using a liquid dielectric constant-measuring device (Model 871, Furuto) and loading 40 ml of each solvent composition according to the examples and the comparative examples in a conical tube at room temperature (25° C.), and the viscosity of the solvent was measured by using a rheometer (Haake) and loading 2 ml of each solvent composition at room temperature (25° C.).

### Evaluation

The ink compositions according to Examples 1 to 6 and Comparative Examples 1 to 3 were measured with respect to viscosity (25° C. and 50° C.). When the viscosity at 50° C. was less than or equal to 15 cps, ink-jetting properties (Inkjet processibility) were evaluated as satisfactory, and in Table 4, when the viscosity was less than or equal to 15 cps, “O” was given, and when the viscosity was greater than 15 cps, “X” was given.

In addition, the dielectric constant was measured by using the dielectric constant-measuring device (Model 871, Furuto) and using 40 ml of a mixed solvent composition respectively corresponding to the ink compositions in a conical tube at room temperature (25° C.), and the viscosity of the mixed solvent was measured by using a rheometer (Haake) and loading 2 ml of the solvent composition at room temperature (25° C.).

The measurement results are shown in Table 4.

TABLE 4

| | | | | | | | | Compar- | Compar- | Compar- |
|---|---|---|---|---|---|---|---|---|---|---|
| | | | | | | | | ative | ative | ative |
| | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 1 | ple 2 | ple 3 |
| Viscosity | 64 | 87 | 85 | 63 | 66 | 67 | 42 | 33 | 60 | 168 |
| (cps) | | | | | | | | | | |
| (25° C.) | | | | | | | | | | |
| Viscosity | 15 | 15 | 15 | 15 | 15 | 15 | 10 | 10 | 15 | 28 |
| (cps) | | | | | | | | | | |
| (50° C.) | | | | | | | | | | |
| Available | 4-11 | 4-11 | 4-11 | 4-11 | 4-11 | 4-11 | 7-9 | 11.2 | 10.4 | 3.2 |
| dielectric | | | | | | | | | | |
| constant | | | | | | | | | | |
| range | | | | | | | | | | |

As shown in Table 4, unlike Comparative Example 3, Examples 1 to 7 and Comparative Examples 1 and 2 all exhibited excellent ink-jetting properties. However, Comparative Example 1, which was an one component system, had a problem of realizing only viscosity, dielectric constant, electrical conductivity of the corresponding solvent, and Comparative Example 2, which was a two component system, had a drawback that when viscosity or a dielectric constant parameter was fixed by using a composition ratio, the other one parameter was not adjusted but fixed. On the other hand, Examples 1 to 7, which were three-component systems, were freely controlled to have a dielectric constant within a range of 4 to 11, while maintaining room temperature viscosity as it is, by adjusting an internal composition ratio of each solvent in the viscosity ranges of 60 cps, 70 cps, and 80 cps at room temperature (25° C.). Accordingly, Examples 1 to 7 exhibited high viscosity at room temperature and secured storage stability and also maintained excellent ink-jetting properties and simultaneously, secured optimal dielectrophoretic characteristics by further freely controlling (adjusting) a dielectric constant.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

1. An ink composition, comprising:
(A) a semiconductor nanorod; and
(B) a mixed solvent including a first solvent, a second solvent, and a third solvent,
wherein the first solvent includes a compound having a viscosity of less than or equal to 70 cps at 25° C. and having a dielectric constant of greater than or equal to 5,
the second solvent includes a compound having a viscosity of greater than or equal to 80 cps at 25° C. or being a solid or having a dielectric constant of greater than or equal to 5, and
the third solvent includes a compound having a dielectric constant of less than 5.

2. The ink composition of claim 1, wherein the first solvent has a viscosity of greater than or equal to 3 cps at 50° C.

3. The ink composition of claim 1, wherein the first solvent comprises a compound represented by Chemical Formula 1-1 or Chemical Formula 1-2: 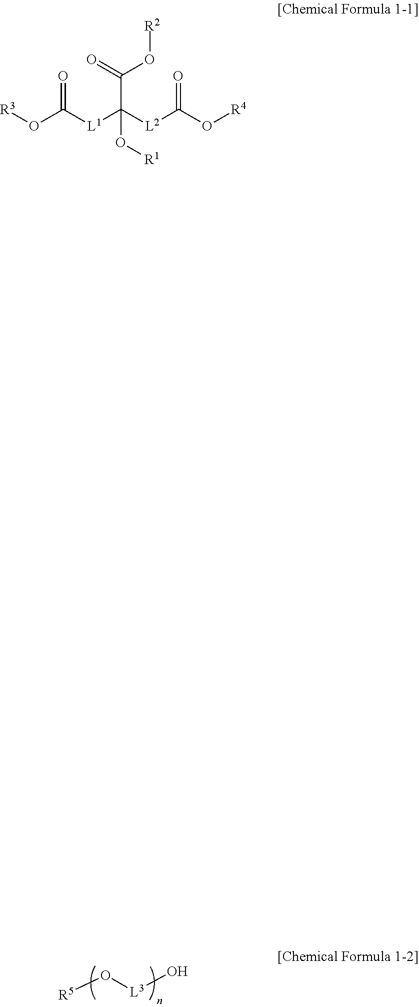
wherein, in Chemical Formula 1-1 and Chemical Formula 1-2,
R¹ is a hydrogen atom or *—C(═O)R′, wherein R′ is a hydrogen atom or a substituted or unsubstituted C1 to C10 alkyl group,
R² to R⁴ are each independently a substituted or unsubstituted C2 to C20 alkyl group,
R⁵ is a substituted or unsubstituted C1 to C20 alkyl group or a substituted or unsubstituted C6 to C20 aryl group substituted with a C2 to C10 alkoxy group,
L¹ to L³ are each independently a substituted or unsubstituted C1 to C20 alkylene group, and
n is an integer of 1 to 20.

4. The ink composition of claim 3, wherein the compound represented by Chemical Formula 1-1 comprises a compound represented by Chemical Formula 1-1-1 or Chemical Formula 1-1-2:

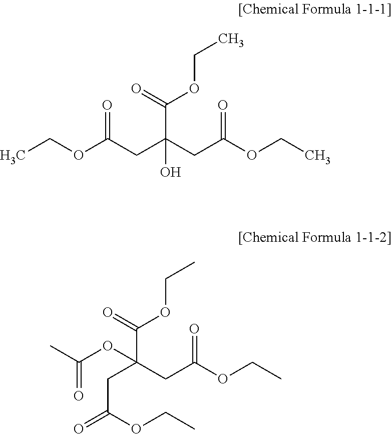

5. The ink composition of claim 3, wherein the compound represented by Chemical Formula 1-2 comprises a compound represented by Chemical Formula 1-2-1 to Chemical Formula 1-2-4:

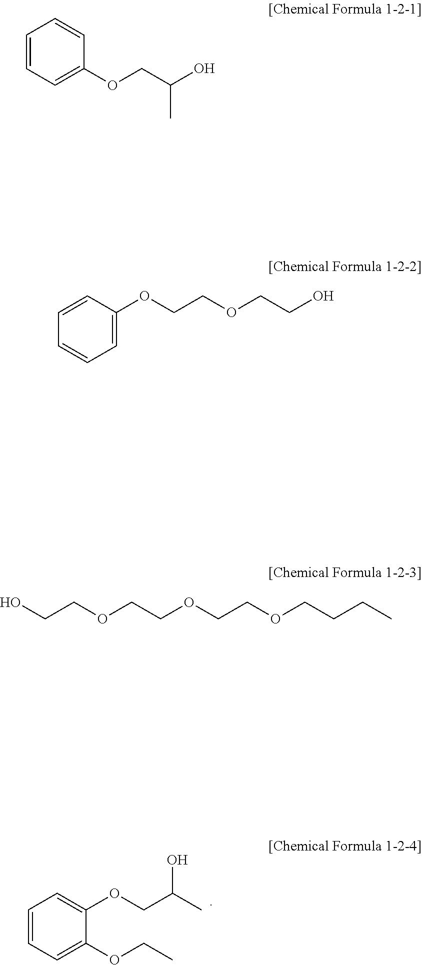

6. The ink composition of claim 1, wherein the second solvent has a viscosity of greater than or equal to 10 cps at 50° C. or is a solid.

7. The ink composition of claim 1, wherein the second solvent comprises a compound represented by one of Chemical Formula 2-1 to Chemical Formula 2-6: 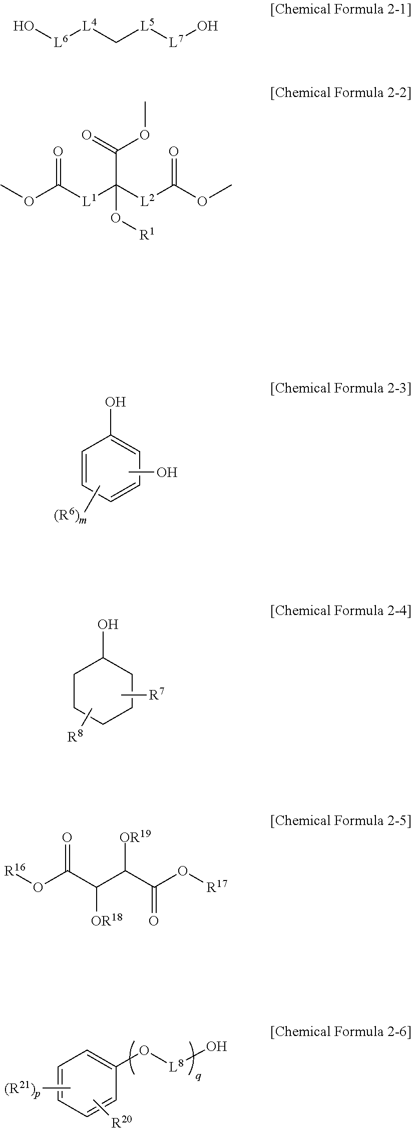
wherein, in Chemical Formula 2-1 to Chemical Formula 2-6,
L¹, L² and L⁴ to L⁸ are each independently a substituted or unsubstituted C1 to C20 alkylene group,
R¹ is a hydrogen atom or *—C(═O)R′, wherein R′ is a hydrogen atom or a substituted or unsubstituted C1 to C10 alkyl group,
R⁶ is a hydroxy group or a substituted or unsubstituted C1 to C20 alkyl group,
R⁷ and R⁸ are each independently a substituted or unsubstituted C1 to C20 alkyl group,
R¹⁶ and R¹⁷ are each independently a hydrogen atom, a substituted or unsubstituted C1 to C20 alkyl group, a substituted or unsubstituted C3 to C20 cycloalkyl group, or a substituted or unsubstituted C6 to C20 aryl group,
R¹⁸ and R¹⁹ are each independently a hydrogen atom or *—(C═O)R¹⁵, wherein R¹⁵ is a substituted or unsubstituted C1 to C20 alkyl group, a substituted or unsubstituted C3 to C20 cycloalkyl group, or a substituted or unsubstituted C6 to C20 aryl group,
R²⁰ is a methoxy group,
R²¹ is a substituted or unsubstituted C1 to C20 alkyl group or a substituted or unsubstituted C1 to C20 alkoxy group,
m is an integer of 1 to 4, and
p is an integer of 1 to 20.

8. The ink composition of claim 7, wherein the compound represented by Chemical Formula 2-1 comprises a compound represented by Chemical Formula 2-1-1:

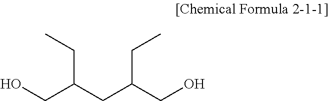

9. The ink composition of claim 7, wherein the compound represented by Chemical Formula 2-2 comprises a compound represented by Chemical Formula 2-2-1:

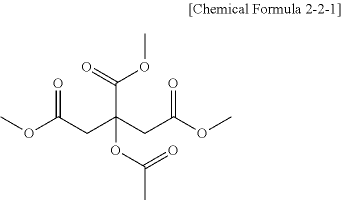

10. The ink composition of claim 7, wherein the compound represented by Chemical Formula 2-3 comprises a compound represented by one of Chemical Formula 2-3-1 to Chemical Formula 2-3-3:

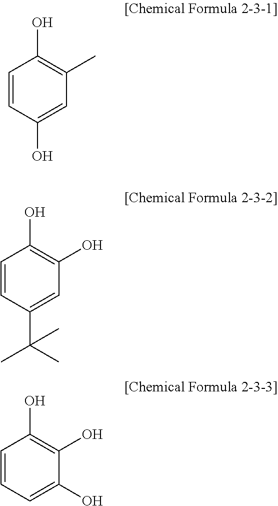

11. The ink composition of claim 7, wherein the compound represented by Chemical Formula 2-4 comprises a compound represented by Chemical Formula 2-4-1:

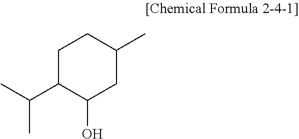

12. The ink composition of claim 7, wherein the compound represented by Chemical Formula 2-5 comprises a compound represented by one of Chemical Formula 2-5-1 and Chemical Formula 2-5-2:

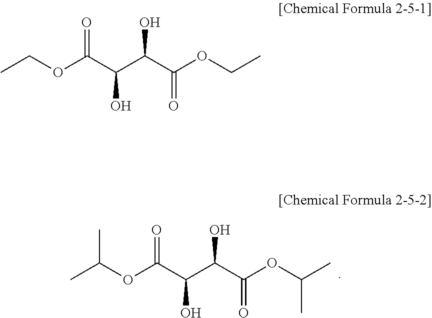

13. The ink composition of claim 7, wherein the compound represented by Chemical Formula 2-6 comprises a compound represented by one of Chemical Formula 2-6-1 to Chemical Formula 2-6-3:

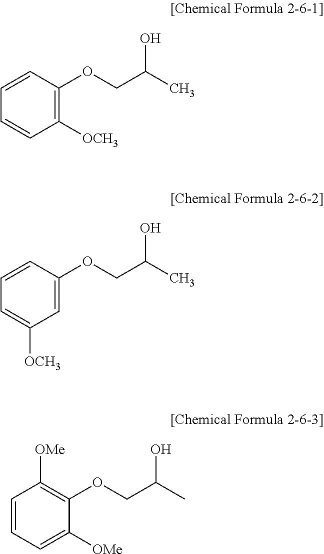

14. The ink composition of claim 1, wherein the third solvent has a viscosity of greater than or equal to 70 cps at 25° C. or is a solid, and has a viscosity of greater than or equal to 3 cps at 50° C.

15. The ink composition of claim 1, wherein the third solvent comprises a compound represented by one of Chemical Formula 3-1 or Chemical Formula 3-2: 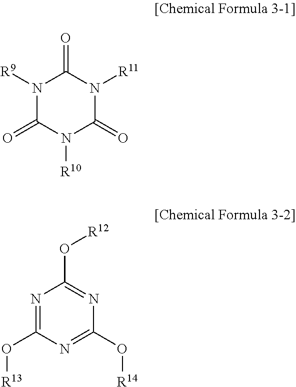
wherein, in Chemical Formula 3-1 and Chemical Formula 3-2,
R⁹ to R¹⁴ are each independently a C1 to C20 alkyl group unsubstituted or substituted with a vinyl group.

16. The ink composition of claim 15, wherein the compound represented by Chemical Formula 3-1 comprises a compound represented by Chemical Formula 3-1-1:

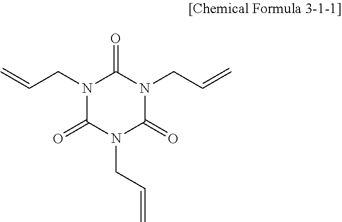 [SMILES: C=CCn1c(=O)n(CC=C)c(=O)n(CC=C)c1=O]

17. The ink composition of claim 15, wherein the compound represented by Chemical Formula 3-2 comprises a compound represented by Chemical Formula 3-2-1:

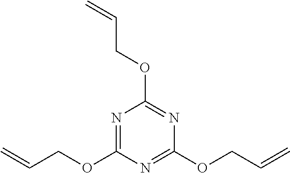 [SMILES: C=CCOc1nc(OCC=C)nc(OCC=C)n1]

18. The ink composition of claim 1, wherein
the first solvent is included in an amount of 10 parts by weight to 50 parts by weight based on 100 parts by weight of the mixed solvent,
the second solvent is included in an amount of 10 parts by weight to 40 parts by weight based on 100 parts by weight of the mixed solvent, and
the third solvent is included in an amount of 20 parts by weight to 50 parts by weight based on 100 parts by weight of the mixed solvent.

19. The ink composition of claim 1, wherein the semiconductor nanorods have a diameter of 300 nm to 900 nm.

20. The ink composition of claim 1, wherein the semiconductor nanorods have a length of 3.5 μm to 5 μm.

21. The ink composition of claim 1, wherein the semiconductor nanorods comprise a GaN-based compound, an InGaN-based compound, or a combination thereof.

22. The ink composition of claim 1, wherein surfaces of the semiconductor nanorods are coated with a metal oxide.

23. The ink composition of claim 22, wherein the metal oxide comprises alumina, silica, or a combination thereof.

24. The ink composition of claim 1, wherein the semiconductor nanorods are included in an amount of 0.01 wt % to 10 wt % based on the total amount of the ink composition.

25. The ink composition of claim 1, wherein the ink composition further comprises malonic acid; 3-amino-1,2-propanediol; a silane-based coupling agent; a leveling agent; a fluorine-based surfactant; or combination thereof.

26. The ink composition of claim 1, wherein the ink composition is an ink composition for an electrophoresis device.

27. A layer manufactured using the ink composition of claim 1.

28. An electrophoresis device comprising the layer of claim 27.

29. A display device comprising the layer of claim 27.
